(19) United States
(12) Patent Application Publication
(10) Pub. No.: US 2026/0006910 A1
(43) Pub. Date: Jan. 1, 2026

(54) SEMICONDUCTOR DEVICE WITH DIELECTRIC ISOLATION STRUCTURE

(71) Applicant: International Business Machines Corporation, Armonk, NY (US)

(72) Inventors: Shay Reboh, Guilderland, NY (US); Lei Zhuang, Ridgefield, CT (US); Ruilong Xie, Niskayuna, NY (US); Shahrukh Khan, Sandy Hook, CT (US); James P Mazza, Saratoga Springs, NY (US)

(21) Appl. No.: 18/758,131

(22) Filed: Jun. 28, 2024

(51) Int. Cl. H01L 27/092; H01L 21/822; H01L 21/8238; H01L 23/528; H01L 29/06; H01L 29/417; H01L 29/423; H01L 29/66; H01L 29/775; H01L 29/786

(52) U.S. Cl. CPC H10D 84/856; H01L 23/5286; H10D 30/014; H10D 30/43; H10D 30/6729; H10D 30/6735; H10D 30/6757; H10D 62/121; H10D 84/0186; H10D 84/0188; H10D 84/038; H10D 88/01

(57) ABSTRACT

A semiconductor structure includes a first set of vertically stacked contacts, a second set of vertically stacked contacts, a first set of stacked transistor devices associated with the first set of vertically stacked contacts, and a second set of stacked transistor devices associated with the second set of vertically stacked contacts. The second set of stacked transistor devices is adjacent to the first set of stacked transistor devices, and a dielectric isolation pillar is disposed between the first set of vertically stacked contacts and the second set of vertically stacked contacts.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure includes a first set of one or more vertically stacked contacts, a second set of one or more vertically stacked contacts, a first set of stacked transistor devices associated with the first set of one or more vertically stacked contacts, and a second set of stacked transistor devices associated with the second set of one or more vertically stacked contacts. The second set of stacked transistor devices is adjacent to the first set of stacked transistor devices, and a dielectric isolation pillar is disposed between the first set of one or more vertically stacked contacts and the second set of one or more vertically stacked contacts.

In an illustrative embodiment, a semiconductor structure includes a first set of vertically stacked metal contacts including a first top metal contact, a first center metal contact, and a first bottom metal contact, a second set of vertically stacked metal contacts including a second top metal contact, a second center metal contact, and a second bottom metal contact, a first stacked nanosheet structure contacting the first set of vertically stacked metal contacts, and a second stacked nanosheet structure contacting the second set of vertically stacked metal contacts. The semiconductor structure also includes a dielectric isolation pillar disposed between the first set of vertically stacked metal contacts and the second set of vertically stacked metal contacts.

In yet another illustrative embodiment, a method includes forming a first transistor structure, forming a second transistor structure, forming a first set of vertically stacked contacts including a first top contact, a first center contact, and a first bottom contact, the first set of vertically stacked contacts contacting the first transistor structure, forming a second set of vertically stacked contacts including a second top contact, a second center contact, and a second bottom contact, the second set of vertically stacked contacts contacting the second transistor structure, and forming a dielectric isolation pillar between the first set of vertically stacked contacts and the second set of vertically stacked contacts.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1 depicts a top view of a semiconductor structure with line Y on which the cross-sectional view of FIGS. 2-22 are based, according to an embodiment of the invention.

FIG. 2 depicts a cross-sectional view of the semiconductor structure corresponding to line Y in FIG. 1 during an intermediate step of a method of fabricating a nanosheet transistor structure, according to an illustrative embodiment.

FIG. 3 depicts a cross-sectional view of the semiconductor structure corresponding to line Y in FIG. 1 following formation of a hardmask layer, according to an illustrative embodiment.

FIG. 4 depicts a cross-sectional view of the semiconductor structure corresponding to line Y in FIG. 1 following formation of an opening in the hardmask layer, according to an illustrative embodiment.

FIG. 5 depicts a cross-sectional view of the semiconductor structure corresponding to line Y in FIG. 1 following a process to extend the opening, according to an illustrative embodiment.

FIG. 6 depicts a cross-sectional view of the semiconductor structure corresponding to line Y in FIG. 1 following formation of a middle-of-the-line (MOL) dielectric isolation pillar, according to an illustrative embodiment.

FIG. 7 depicts a cross-sectional view of the semiconductor structure corresponding to line Y in FIG. 1 following formation of a first contact opening, according to an illustrative embodiment.

FIG. 8 depicts a cross-sectional view of the semiconductor structure corresponding to line Y in FIG. 1 following formation of a first contact layer, according to an illustrative embodiment.

FIG. 9 depicts a cross-sectional view of the semiconductor structure corresponding to line Y in FIG. 1 following formation of a second contact layer, an additional interlayer dielectric (ILD) layer, a set of vias, frontside back-end-of-line (BEOL) interconnects, a carrier wafer, a backside ILD layer, and backside processing, according to an illustrative embodiment.

FIG. 10 depicts a cross-sectional view of the semiconductor structure corresponding to line Y in FIG. 1 following further backside processing, according to an illustrative embodiment.

FIG. 11 depicts a cross-sectional view of the semiconductor structure corresponding to line Y in FIG. 1 following a planarization process, according to an illustrative embodiment.

FIG. 12 depicts a cross-sectional view of the semiconductor structure corresponding to line Y in FIG. 1 following deposition of ILD material, according to an illustrative embodiment.

FIGS. 13-18 depict cross-sectional views of the semiconductor structure corresponding to line Y in FIG. 1 in accordance with a first alternative process starting from FIG. 3, according to an illustrative embodiment.

FIGS. 19-21 depict cross-sectional views of the semiconductor structure corresponding to line Y in FIG. 1 in accordance with a second alternative process starting from FIG. 15, according to an illustrative embodiment.

FIG. 22 depicts a cross-sectional view of a semiconductor structure having a MOL dielectric isolation pillar, according to an illustrative embodiment.

### DETAILED DESCRIPTION

This disclosure relates generally to semiconductor devices, and more particularly to semiconductor structures having a source/drain region with a protective liner layer, and methods for their fabrication. However, it is to be understood that embodiments of the present disclosure are not limited to the illustrative methods, apparatus, systems, and devices but instead are more broadly applicable to other suitable methods, apparatus, systems, and devices.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on,” “overlying,” “atop,” “on top,” “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment,” as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick,” “thickness,” “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick,” “thickness,” “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s). Other suitable techniques, such as sidewall image transfer (SIT), self-aligned double patterning (SADP), self-aligned quadruple patterning (SAQP), self-aligned multiple patterning (SAMP) can be used to etch or pattern.

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL. The conductive contacts of the MOL layer provide electrical connections between the integrated circuitry of the FEOL layer and a first level of metallization of a BEOL structure that is formed over the FEOL/MOL layers.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

In general, for stacked FET structures, the bottom FET needs to be connected to one or more frontside signal lines. For stacked FETs having highly scaled cells, there is an increased risk of shorts between metal contacts of adjacent cells. At least some illustrative embodiments described herein provide an integration scheme to avoid such shorts.

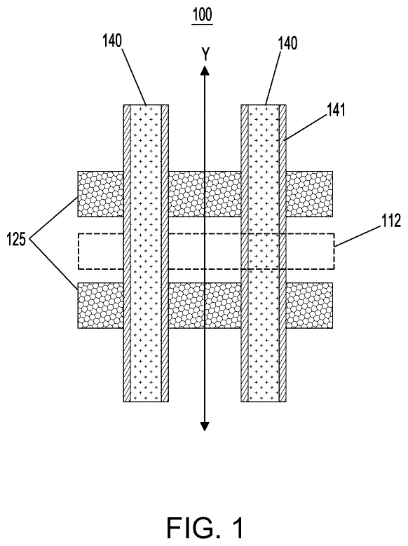

Referring now to the drawings, in which like numerals represent the same or similar elements, FIGS. 1-21 illustrate various processes for fabricating semiconductor structures with a MOL dielectric isolation pillar. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1-21 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

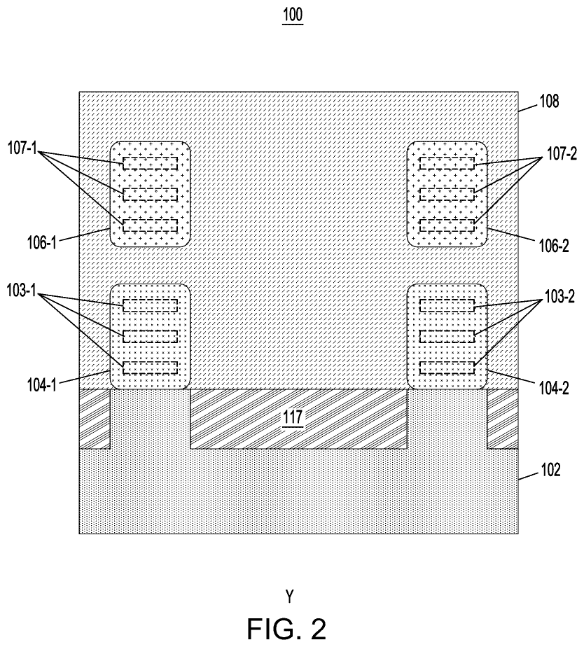

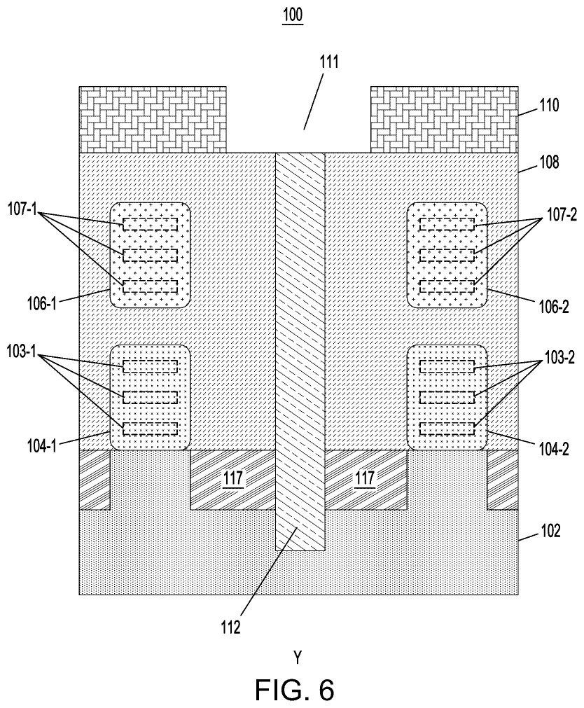

FIGS. 1-12 show a semiconductor structure 100 in accordance with an illustrative embodiment. FIG. 1 depicts a top view of the semiconductor structure 100 with line Y on which the cross-sectional views of FIGS. 2-22 are based. In FIG. 1, the semiconductor structure includes active regions 125, gate structures 140, and gate spacers 141. The dashed region in FIG. 1 in FIG. 1 indicates a possible location in which a middle-of-the-line (MOL) dielectric isolation pillar 112 is formed, as explained in more detail in FIG. 6. It is noted that the region of the MOL dielectric isolation pillar 112 shown in FIG. 1 is not intended to be limiting, and in other embodiments the MOL dielectric isolation pillar 112 can correspond to a different region, such as between the two gate structures 140. The active regions 125 correspond to areas of the semiconductor structure 100 where bottom source/drain regions 104-1 and 104-2 (collectively bottom source/drain regions 104) and top source/drain regions 106-1 and 106-2 (collectively top source/drain regions 106) are formed, as shown in FIGS. 2-22.

Referring to FIG. 1 and to the cross-sectional view in FIG. 2 corresponding to the line Y, the semiconductor structure 100 is shown during an intermediate step of a method of fabricating a nanosheet transistor structure having one or more nanosheet devices, according to an embodiment of the invention. The semiconductor structure 100 includes a semiconductor substrate 102, bottom FET structures having respective bottom channel layers 103-1 and 103-2 (collectively referred to as bottom channel layers 103) and top FET structures having respective top channel layers 107-1 and 107-2 (collectively referred to as top channel layers 107). The bottom FET structures are associated with respective ones of the bottom source/drain regions, and the top FET structures are associated with respective ones of the top source/drain regions 106. It is noted that the bottom channel layers 103 and the top channel layers 107 are positioned along the gate structures 140 shown in FIG. 1. Thus, in FIGS. 2-22, the bottom channel layers 103 and the top channel layers 107 are projected onto the cross-sectional views shown as indicated by the dashed regions.

The semiconductor substrate 102 may be formed of any suitable semiconductor material, including various silicon-containing materials including but not limited to silicon (Si), silicon germanium (SiGe), and multi-layers thereof. Although silicon is the predominantly used semiconductor material in wafer fabrication, alternative semiconductor materials can be employed as additional layers, such as, but not limited to, SiGe, germanium (Ge), gallium arsenide (GaAs), gallium indium arsenide (InGaAs), cadmium telluride (CdTe), zinc selenide (ZnSe), etc. In one illustrative embodiment, the semiconductor substrate 102 is silicon.

In some embodiments, each of the bottom FET structures may be vertically aligned with the corresponding top FET structure. The bottom FET structures and the top FET structures may be formed from a plurality of stacked sacrificial layers (not shown) and the channel layers 103 and 107. The channel layers 103 and 107 may be formed of Si or another suitable material (e.g., a material similar to that used for the semiconductor substrate 102). The sacrificial layers are illustratively formed of a sacrificial material, such that they can be etched or otherwise removed selectively with respect to at least the channel layers 103 and 107. In some embodiments, the sacrificial layers are formed of SiGe. For example, the sacrificial layers may have a relatively higher percentage of Ge (e.g., 55% Ge) or a relatively lower percentage of Ge (e.g., 25% Ge). In some embodiments, the bottom FET structures may have an n-type conductivity and the top FET structures may have a p-type conductivity. In some embodiments, the bottom FET structures may have a p-type conductivity and the top FET structures may have an n-type conductivity.

In an illustrative embodiment, the gate structures 140 are formed after a replacement metal gate (RMG) process in which the sacrificial layers are removed and replaced with the gate structure 140. In various embodiments, the gate structure 140 may include a gate dielectric layer and a gate conductor layer. The gate dielectric layer may be formed of a high-k dielectric material. Suitable high-k dielectric materials include metal oxides such as HfO2, hafnium silicon oxide (Hf—Si—O), hafnium silicon oxynitride (HfSiON), lanthanum oxide (La2O3), lanthanum aluminum oxide (LaAlO3), zirconium oxide (ZrO2), zirconium silicon oxide, zirconium silicon oxynitride, tantalum oxide (Ta2O5), titanium oxide (TiO2), barium strontium titanium oxide, barium titanium oxide, strontium titanium oxide, yttrium oxide (Y2O3), aluminum oxide (Al2O3), lead scandium tantalum oxide, and lead zinc niobate. The high-k dielectric material may further include dopants such as lanthanum (La), aluminum (Al), and magnesium (Mg). The gate dielectric layer may have a uniform thickness.

In various embodiments, the gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

In some embodiments, the gate spacers 141 are formed on sides of the gate structure 140. The gate spacer material can comprise one or more dielectrics, including but not necessarily limited to silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), silicon oxide (SiOₓ) (where x is for example, 2, 1.99 or 2.01) and combinations thereof. The gate spacers 141 can be formed by any suitable techniques such as deposition followed by directional etching. Deposition may include but is not limited to chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). Directional etching may include but is not limited to reactive ion etching (RIE).

In some embodiments, isolation regions 117 (e.g., shallow trench isolation (STI) regions) comprising a fill portion and a liner portion are formed in the semiconductor substrate 102 between the stacks of channel layers 103 and 107 and gate structures 140 and between source/drain regions 104 and 106, as shown. In illustrative embodiments, the fill portion comprises an oxide (e.g., SiOₓ) and the liner portion comprises a nitride (e.g., SiN, SiON, SiCN, BN, SiBCN, SiOCN). The isolation regions 117 fill in recessed portions of the semiconductor substrate 102.

The bottom source/drain regions 104 and the top source/drain regions 106 are epitaxially grown between respective stacks of the channel layers 103 and 107. The bottom source/drain regions 104 comprise epitaxial layers grown from the sides of the channel layers 103, as well as from the top surface of the semiconductor substrate 102, for example. The top source/drain regions 106 comprise epitaxial layers grown from the sides of the channel layers 107, as well as from a top surface of a sacrificial layer (not shown) disposed between the channel layers 103 and 107. For example, the sacrificial layer can include a middle dielectric isolation (MDI) layer.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of an in-situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

An interlayer dielectric (ILD) layer 108 fills in portions on and around the bottom source/drain regions 104 and the top source/drain regions 106. The ILD layer 108 is deposited using deposition techniques such as, for example, CVD, PECVD, RFCVD, PVD, ALD, MBD, PLD, and/or LSMCD, followed by a planarization process, such as, CMP. The ILD layer 108 may comprise, for example, SiOₓ, SiOC, SiOCN or some other dielectric material.

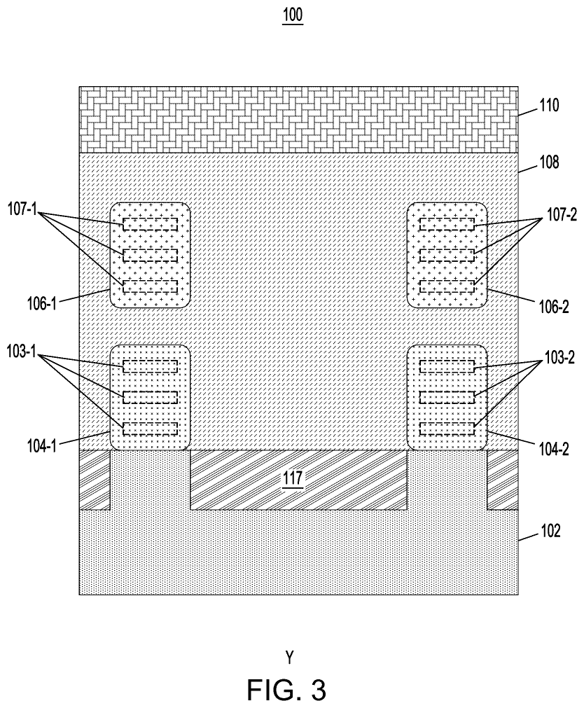

Referring now to FIG. 3, the semiconductor structure 100 is shown following formation of a hardmask (HM) layer 110. The HM layer 110 is deposited on the top surface of the ILD layer 108 by conventional deposition techniques such as ALD, CVD, PVD, etc. The HM layer 110 can be composed of a flowable organic material such as, for example, a spin-on-carbon (SOC), Si₃N₄, SiBCN, SINC, SiN, SiCO, SiO₂, and SiNOC.

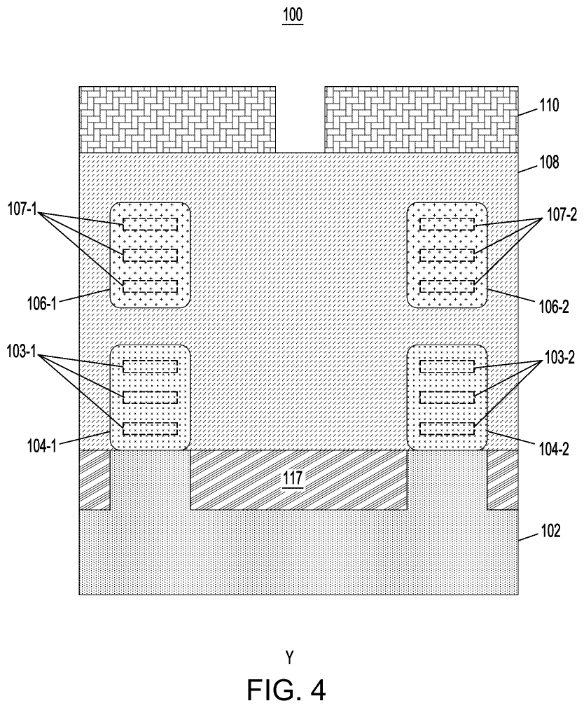

Referring now to FIG. 4, the semiconductor structure 100 is shown following an opening being formed in the HM layer 110. In some embodiments, the opening is made utilizing conventional lithographic and selective etch processes such as a wet or dry etching process in the HM layer 110 to form an opening. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As another example, a wet etching process may include etching in DHF, potassium hydroxide (KOH) solution, ammonia, a solution containing hydrofluoric acid (HF), nitric acid (HNO₃), and/or acetic acid (CH₃COOH), or other suitable wet etchants.

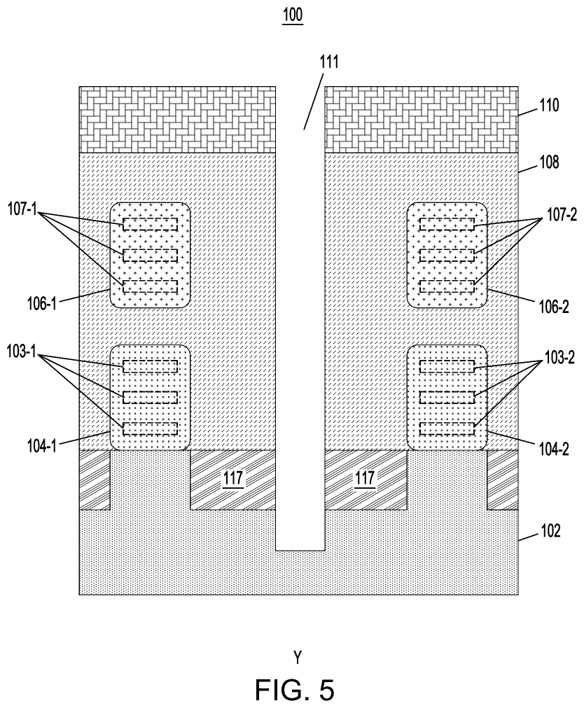

Referring now to FIG. 5, the semiconductor structure 100 is shown following an extension of the opening in the HM layer 110, thereby forming opening 111. For example, the opening 111 can be formed by removing the portions of the ILD layer 108, the isolation region 117, and the semiconductor substrate 102 using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry. In other embodiments, the opening 111 may be formed such that it extends down to a level corresponding to the bottom surface of the bottom FET structures or into the isolation regions 117 without extending into the semiconductor substrate 102, for example.

Referring now to FIG. 6, the semiconductor structure 100 is shown following formation of a MOL dielectric isolation pillar 112. The MOL dielectric isolation pillar 112 is formed by filling the opening 111 with a dielectric material. The MOL dielectric isolation pillar 112 may be formed of a dielectric material such as silicon dioxide (SiO₂), silicon oxycarbide (SiOC), silicon oxynitride (SiON), etc. In some embodiments, the MOL dielectric isolation pillar 112 is formed of a material comprising silicon (Si) and nitrogen (N) and may also be formed of a material comprising carbon (C) and/or oxygen (O). In some embodiments, the opening of the HM layer 110 above the ILD layer 108 and the MOL dielectric isolation pillar 112 is widened utilizing conventional lithographic and selective etch processes such as wet and/or dry etching processes.

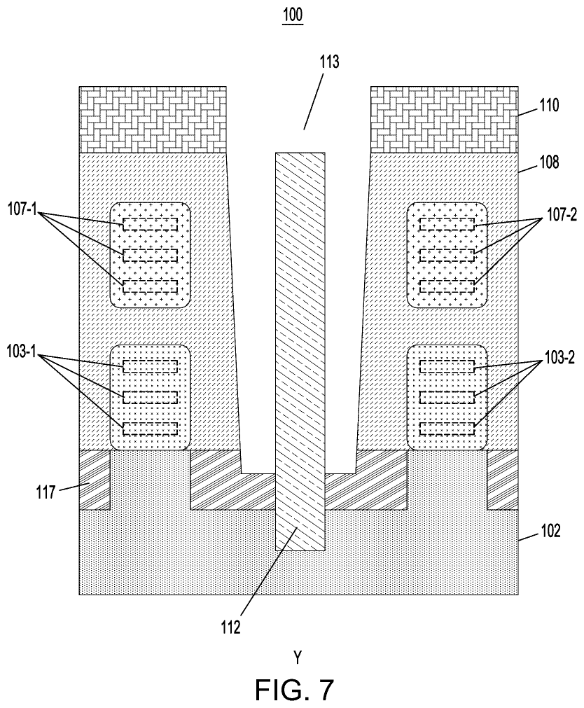

Referring now to FIG. 7, the semiconductor structure 100 is shown following the formation of a first contact opening 113, according to an illustrative embodiment. The first contact opening 113 is formed in the ILD layer 108 to expose at least a portion of the sidewalls of the MOL dielectric isolation pillar 112 through the opening in the HM layer 110 using a suitable wet or dry etch, for example.

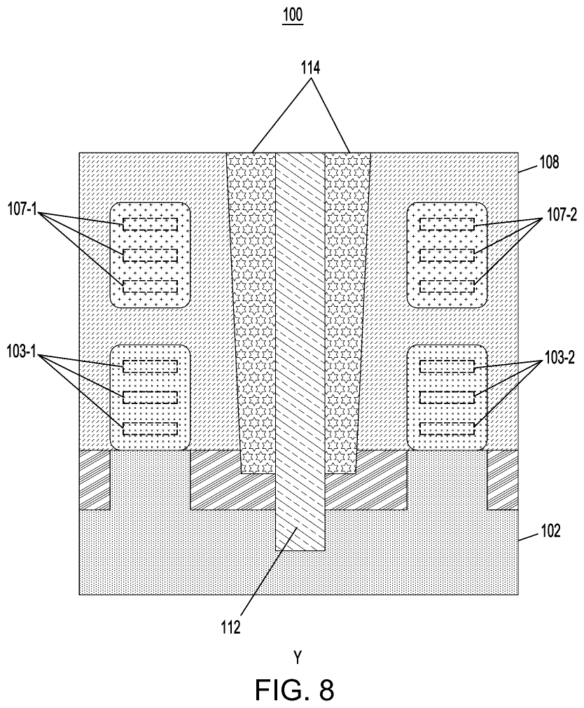

Referring now to FIG. 8, the semiconductor structure 100 is shown following the formation of a first contact layer 114 (e.g., a S/D contact layer). The first contact layer 114 is formed by depositing a suitable high-conductive metal in the first contact opening 113. Suitable high-conductive metals include, for example, a silicide liner such as Ti, Ni, NiPt, an adhesion metal liner such as TIN, followed by filling conductive material such as, for example, tungsten (W), aluminum (Al), copper (Cu), cobalt (Co), ruthenium (Ru), molybdenum (Mo), or any other suitable conductive material. In various embodiments, the high-conductive metal can be deposited by ALD, CVD, PVD, and/or plating. The high-conductive metal may then be planarized using, for example, a planarizing process such as CMP to remove excess conductive metal material as well as the HM layer 110. Other planarization processes may include grinding and polishing. In some embodiments, the first contact layer 114 is disposed along the exposed portions of the sidewalls of the MOL dielectric isolation pillar 112 and the ILD layer 108 that are adjacent to each of the bottom FET structures and each of the top FET structures.

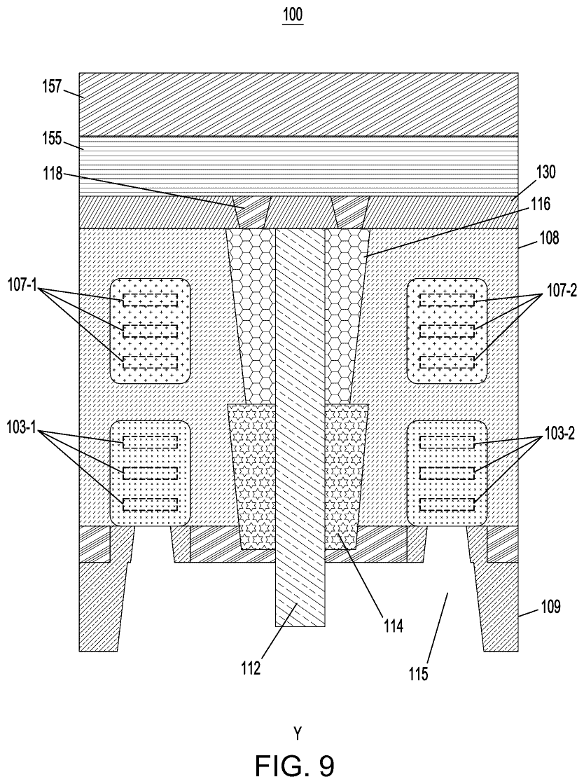

Referring now to FIG. 9, the semiconductor structure 100 is shown following the formation of a second contact layer 116, an additional ILD layer 130, a set of vias 118, a frontside BEOL interconnects 155, a carrier wafer 157, and a backside ILD layer 109, and backside processing. In some embodiments, portions of the first contact layer 114 are removed utilizing conventional lithographic and selective etch processes such as a wet or dry etching process to form an opening. In embodiments, additional ILD material is deposited to fill in the opening to extend the ILD layer 108. The second contact layer 116 is then formed in the ILD layer 108 by similar processes as the first contact layer 114. The second contact layer 116 can be formed of a suitable high-conductive metal. In some embodiments, the conductive metal used to form the first contact layer 114 is the same as the conductive metal used to form the second contact layer 116. In some embodiments, the conductive metal used to form the first contact layer 114 is different from the conductive metal used to form the second contact layer 116. The high-conductive metal may then be planarized using, for example, a planarizing process such as CMP. Other planarization processes can include grinding and polishing.

The additional ILD layer 130 is formed on top of the ILD layer 108 by depositing additional ILD material. In some embodiments, the set of vias 118 are formed by similar processes and similar conductive metals as the first contact layer 114 and the second contact layer 116. In some embodiments, the vias 118 are disposed so that a bottom surface of each of the vias 118 is disposed on a corresponding top surface of the second contact layer 116. The conductive metal can then be planarized using, for example, a planarizing process such as CMP. Other planarization processes can include grinding and polishing. The frontside BEOL interconnects 155 are then formed.

The carrier wafer 157 is bonded to the frontside BEOL interconnects 155. The frontside BEOL interconnects 155 include various BEOL interconnect structures which may electrically connect to the MOL metallization layers (e.g., the set of vias 118 and/or the contact layers 114 and 116). The carrier wafer 157 may be formed of materials similar to that of the semiconductor substrate 102 and may be formed over the frontside BEOL interconnects 155 using a wafer bonding process, such as dielectric-to-dielectric bonding.

The semiconductor structure 100 can then be “flipped” (e.g., rotated 180 degrees) so that the semiconductor structure 100 is inverted. The semiconductor substrate 102 is then removed from the backside of the semiconductor structure 100. Etchants for removing the semiconductor substrate 102 include, for example, KOH and TMAH.

Following removal of the semiconductor substrate 102, a backside ILD layer 109 is deposited using deposition techniques such as, for example, CVD, PECVD, RFCVD, PVD, ALD, MBD, PLD, and/or LSMCD, followed by a planarization process, such as CMP. The backside ILD layer 109 may comprise, for example, SiOₓ, SiOC, SiOCN or some other dielectric.

In some embodiments, the backside processing can include backside ILD layer patterning. In some embodiments, the backside ILD layer patterning includes depositing one or more masks to form an opening 115 in the backside ILD layer 109 that exposes portions of the bottom surface and sidewalls of the MOL dielectric isolation pillar 112, portions of the bottom surfaces of the first contact layer 114, portions of the isolation regions 117, portions of the bottom surfaces of the bottom source/drain regions 104, as shown. The opening 115 can be formed using, for example, a dry etching process using a RIE or IBE process, a wet chemical etching process or a combination of these etching processes. A dry etch may be performed using a plasma. Such wet or dry etch processes include, for example, IBE by Ar/CHF3 based chemistry.

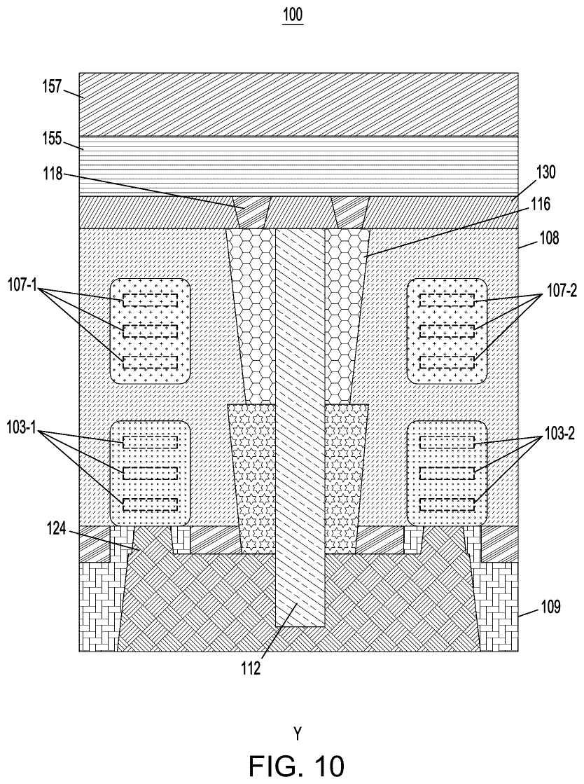

Referring now to FIG. 10, the semiconductor structure 100 is shown following further backside wafer processing. In some embodiments, a suitable conductive metal is deposited in the opening 115 to form a third contact layer 124. In some embodiments, the third contact layer 124 can be connected to portions of the bottom source/drain regions 104. In some embodiments, the third contact layer 124 can be used for connecting the bottom FET structure to one or more frontside signal lines, for example.

The material of the third contact layer 124 can be a conductive material, such as electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the opening 115 before depositing the conductive material. Deposition of the conductive material can be performed using one or more deposition techniques, including but not necessarily limited to CVD, PECVD, PVD, ALD, MBD, PLD, LSMCD, and/or spin-on coating.

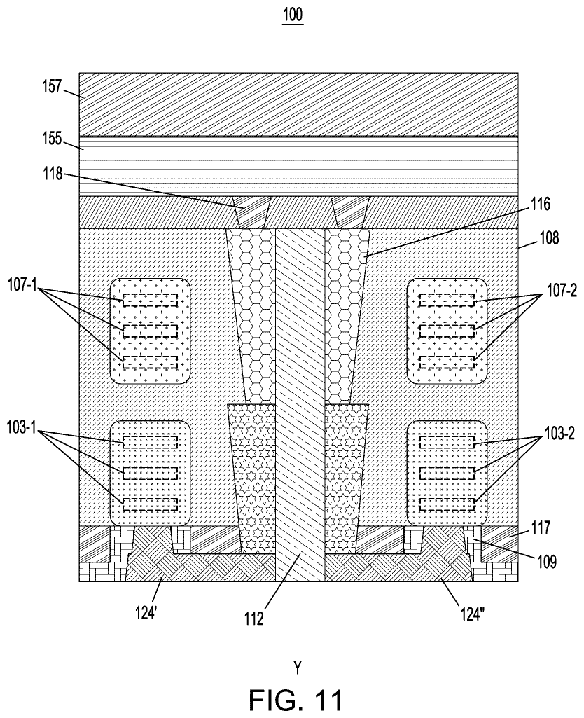

Referring now to FIG. 11, the semiconductor structure 100 is shown following a planarization process. A planarization process, such as CMP, is performed to remove at least bottom portions of the third contact layer 124, the ILD layer 109, and the MOL dielectric isolation pillar 112. The planarization process results in the third contact layer 124 being divided into two parts, 124′ and 124″, which are separated by the MOL dielectric isolation pillar 112. In some embodiments, the third contact layer parts 124′ and 124″ may be self-aligned to the MOL dielectric isolation pillar 112.

In at least one alternative embodiment, bottom portions of the third contact layer 124 and the ILD layer 109 can be removed without remove portions of the MOL dielectric isolation pillar 112, such that the MOL dielectric isolation pillar 112 extends below the bottom surfaces of the ILD layer and the third contact layer 124.

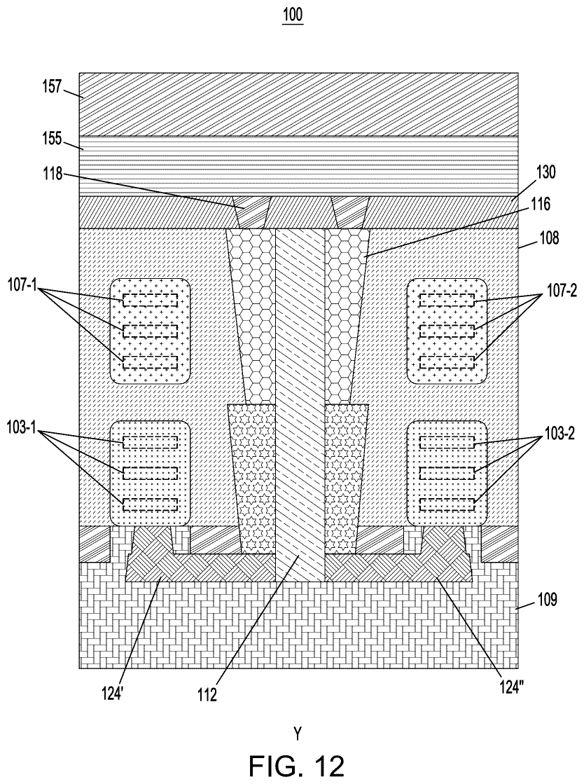

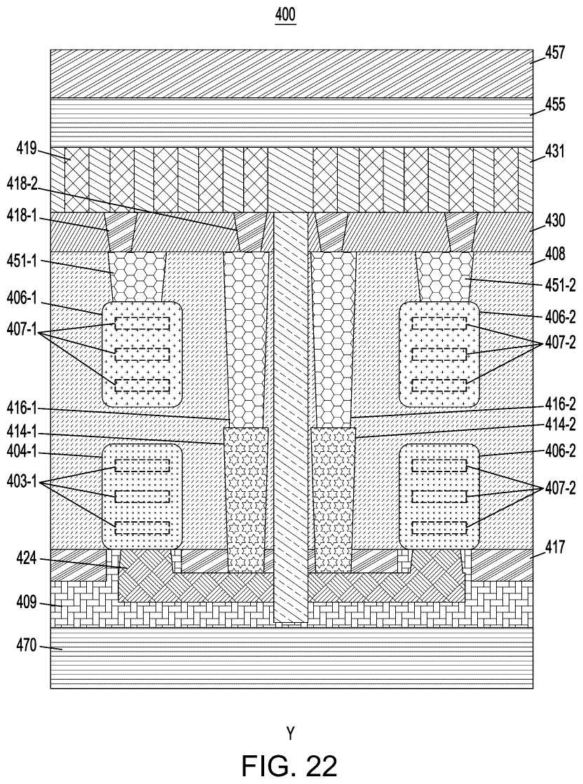

Referring now to FIG. 12, the semiconductor structure 100 is shown following deposition of additional ILD material. The additional ILD material is deposited on the backside ILD layer 109 and the bottom surfaces of the third contact layer parts 124′ and 124″ to expand the backside ILD layer 109. In some embodiments, various backside power delivery network (BSPDN) layers (or backside interconnects) can be formed on the backside ILD layer 109. The BSPDN structures can include, for example, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits. An example of a semiconductor device with such backside interconnects is described in more detail in conjunction with FIG. 22, for example.

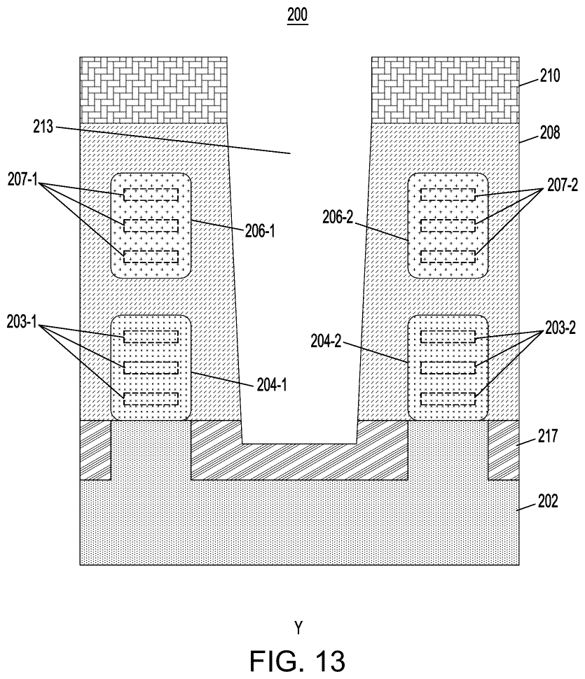

FIGS. 13-18 show a semiconductor structure 200 in accordance with a first alternative illustrative embodiment starting from FIG. 2 of the semiconductor structure 100 for use at a first-intermediate fabrication stage. This first alternative illustrative embodiment depicts a semiconductor structure 200 that includes a semiconductor substrate 202, bottom FET structures having respective bottom channel layers 203-1 and 203-2 (collectively referred to as bottom channel layers 203), an ILD layer 208, top FET structures having respective top channel layers 207-1 and 207-2 (collectively referred to as top channel layers 207), and isolation regions 217. The bottom FET structures are associated with respective bottom source/drain regions 204-1 and 204-2 (collectively referred to as bottom source/drain regions 204), and the top FET structures are associated with respective top source/drain regions 206-1 and 206-2 (collectively referred to as top source/drain regions 206). A first contact opening 213 has been formed in the ILD layer 208 using HM layer 210. Unlike the process depicted in FIGS. 2-12, the first contact opening 213 can be formed prior to an MOL dielectric isolation pillar 212. The first contact opening 213 can be formed using similar processes as used to form the first contact opening 113.

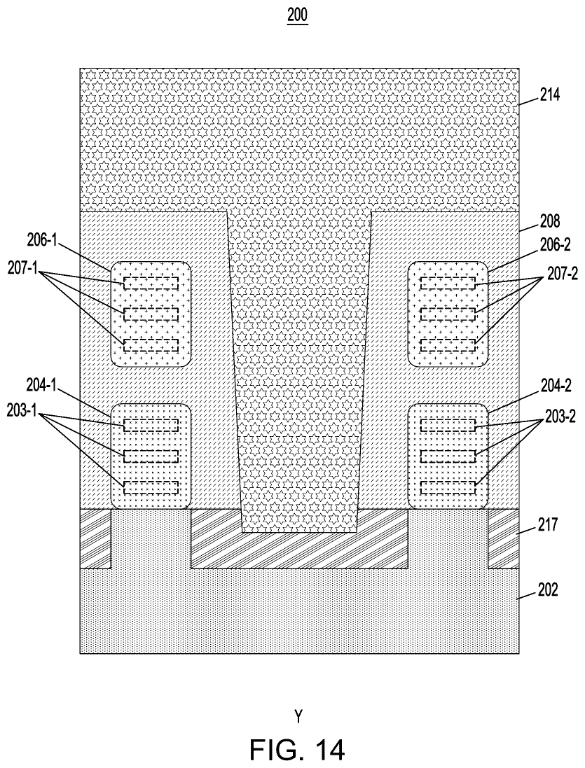

Referring now to FIG. 14, the semiconductor structure 200 is shown following a metal fill. A high-conductive metal is deposited in the first contact opening 213 to form a first contact layer 214. The first contact layer 214 can be formed using similar processes and materials as the first contact layer 114, for example.

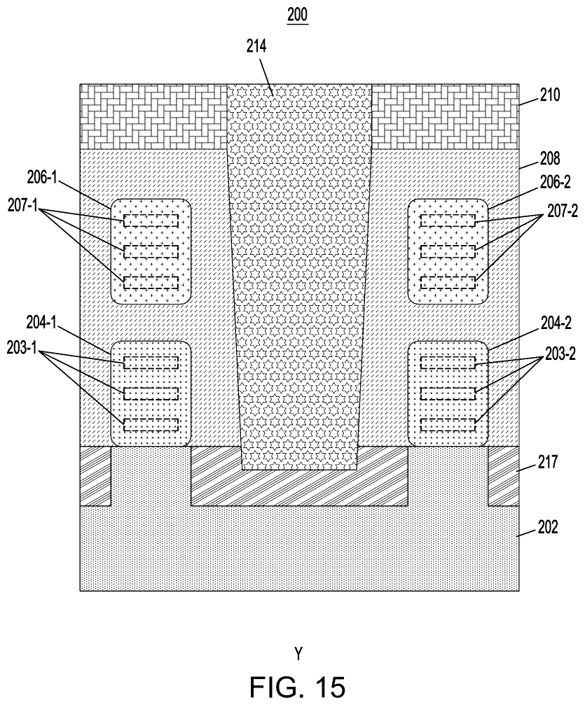

Referring now to FIG. 15, the semiconductor structure 200 is shown following a planarization process. The first contact layer 214 may be planarized to expose a top surface of HM layer 210 so that a top surface of the first contact layer 214 is disposed between the portions of the HM layer 210. The high-conductive metal can be planarized using, for example, a planarizing process such as CMP. Other planarization processes can include grinding and polishing.

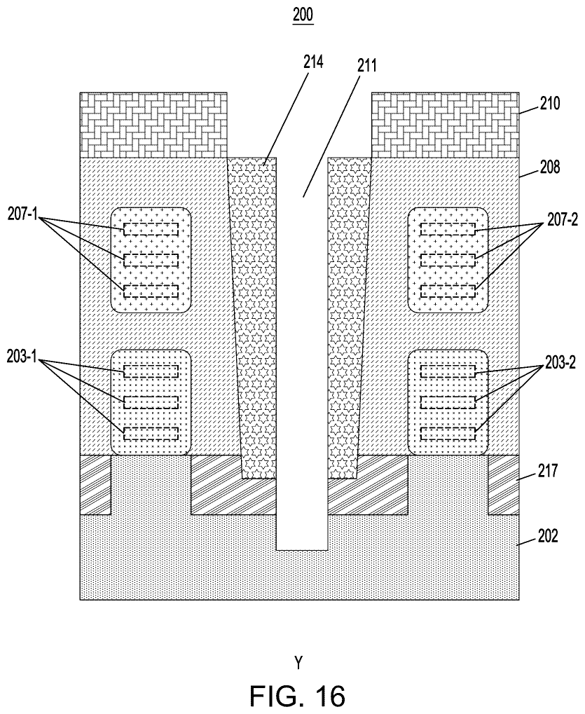

Referring now to FIG. 16, the semiconductor structure 200 is shown following the formation of an opening 211. In some embodiments, portions of the first contact layer 214 are removed so that the top portion of the first contact layer 214 is level with the top surface of the ILD layer 208. Then, the opening 211 is formed using any suitable wet or dry etch process. In the example shown in FIG. 16, the opening 211 extends into a portion of the semiconductor substrate 202 and divides the first contact layer 214 and a portion of the isolation regions 217.

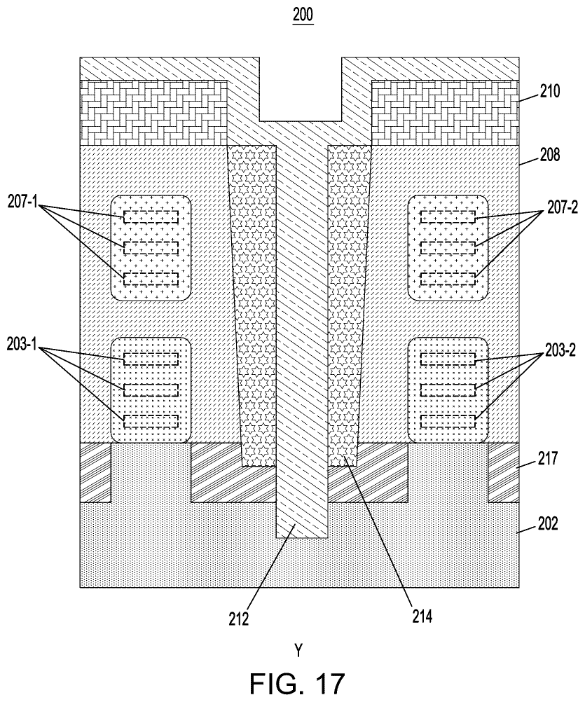

Referring now to FIG. 17, the semiconductor structure 200 is shown following a dielectric fill. A dielectric material is used to fill the opening 211 and extends up the sidewalls of the exposed HM layer 210 and the ILD layer 208 to the top surfaces of the portions of the HM layer 210 to form a MOL dielectric isolation pillar 212. The dielectric material used to form the MOL dielectric isolation pillar 212 may be the same or similar material used to form the MOL dielectric isolation pillar 112.

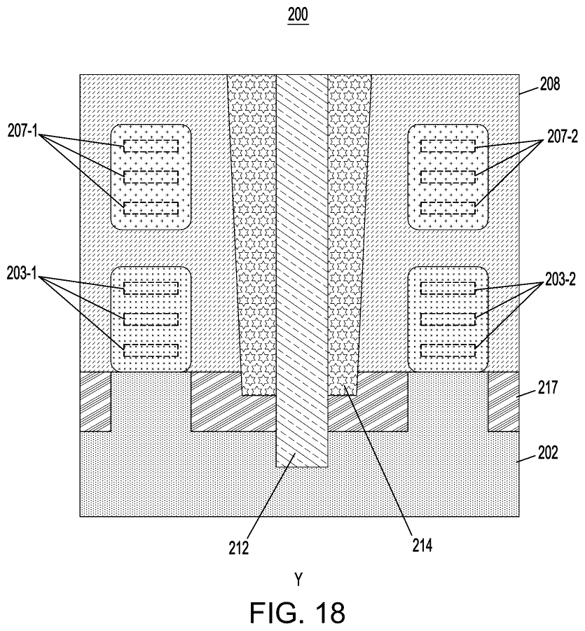

Referring now to FIG. 18, the semiconductor structure 200 is shown following planarization of the top portions of the MOL dielectric isolation pillar 212 and the HM layer 210. The planarization can be performed using, for example, one or more suitable planarization processes such as CMP. Other planarization processes can include grinding and polishing. Following the planarization process, the top surface of the MOL dielectric isolation pillar 212 is level with the top surface of the ILD layer 208, and the HM layer 210 is removed. In some embodiments, the fabrication of the semiconductor structure 200 then continues as described in FIG. 9. In other embodiments, the fabrication of the semiconductor structure 200 can continue as described in FIG. 9, but without removing portions of the first contact layer 216 and forming a second contact layer.

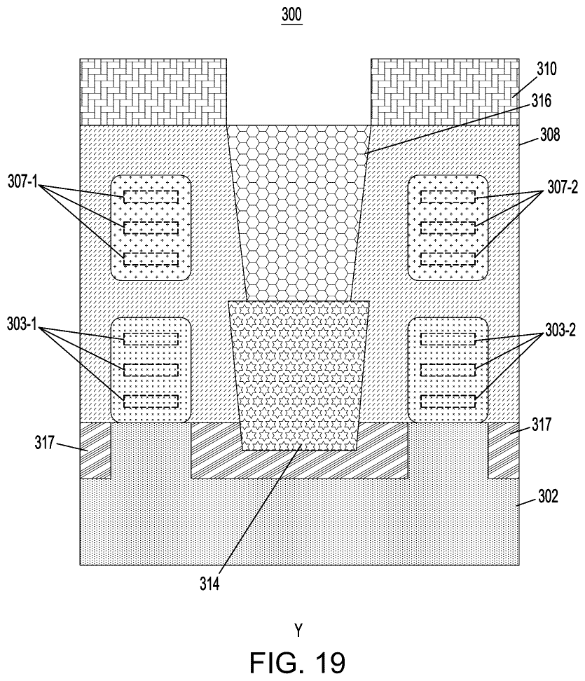

FIGS. 19-21 show a semiconductor structure 300 in accordance with a second alternative illustrative embodiment starting from FIG. 15 of the semiconductor structure 200 for use at a first-intermediate fabrication stage. In this second alternative illustrative embodiment, similar to semiconductor structures 100 and 200, the semiconductor structure 300 includes a semiconductor substrate 302, bottom FET structures having respective bottom channel layers 303-1 and 303-2 (collectively referred to as bottom channel layers 303), an ILD layer 308, and top FET structures having respective top channel layers 307-1 and 307-2 (collectively referred to as top channel layers 307), and isolation regions 317. The bottom FET structures are associated with respective bottom source/drain regions 304-1 and 304-2 (collectively referred to as bottom source/drain regions 304), and the top FET structures are associated with respective top source/drain regions 306-1 and 306-2 (collectively referred to as top source/drain regions 306).

Referring now to FIG. 19, a first contact layer 314 and a second contact layer 316 have been formed in a similar manner as the first contact layer 114 and the second contact layer 116, however, the contact layers 314 and 316 are formed prior to the formation of a MOL dielectric isolation pillar. An HM layer 310 has also been formed on the top surface of the ILD layer 308.

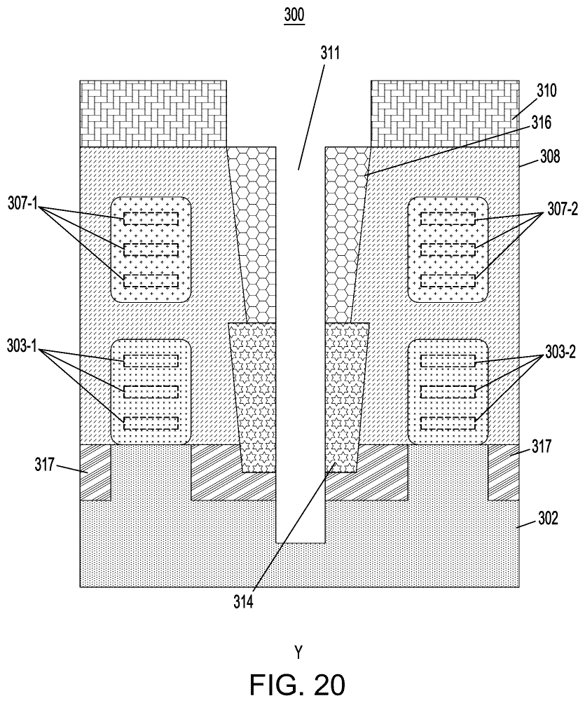

Referring now to FIG. 20, the semiconductor structure 300 is shown following formation of an opening 311. In this embodiment, the opening 311 extends into a portion of the semiconductor substrate 302 and through a portion of the isolation regions 317 and the contact layers 314 and 316. The opening can be formed using any suitable process, such as a suitable wet or dry etch process. In some embodiments, the opening 311 may be disposed between the channel layers 303-1 and 307-1 and the channel layers 303-2 and 307-2, as shown in FIG. 20.

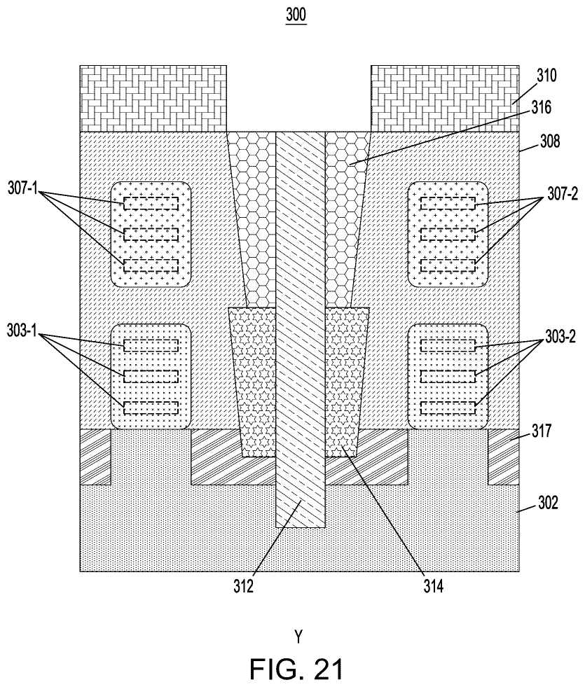

Referring now to FIG. 21, the semiconductor structure 300 is shown following formation of a MOL dielectric isolation pillar 312. The MOL dielectric isolation pillar 312 is formed by filling the opening 311 with dielectric material (e.g., the same or similar dielectric material used to form the MOL dielectric isolation pillars 112 and 212). The fabrication of the semiconductor structure 300 then continues in a similar manner as the process depicted in FIGS. 9-12, for example.

Referring now to FIG. 22, a semiconductor structure 400 is shown having a MOL dielectric isolation pillar 412, according to an illustrative embodiment. In this illustrative embodiment, similar to the semiconductor structure 100, the semiconductor structure 400 includes: a semiconductor substrate 402; bottom FET structures having respective bottom channel layers 403-1 and 403-2 (collectively referred to as bottom channel layers 403); top FET structures having respective top channel layers 407-1 and 407-2 (collectively referred to as top channel layers 407); ILD layers 408, 409 and 430; isolation regions 417; and a set of vias including vias 418-1 and 418-2). The bottom FET structures are associated with respective bottom source/drain regions 404-1 and 404-2 (collectively referred to as bottom source/drain regions 404), and the top FET structures are associated with respective top source/drain regions 406-1 and 406-2 (collectively referred to as top source/drain regions 406).

The semiconductor structure 400 also includes source/drain contacts 451-1 and 451-2 (collectively top source/drain contacts 451) that contact top surfaces of the source/drain regions 406. The source/drain contacts 451-1 and 451-2 can be formed using similar processes and materials as described for the contact layers 114 and 116, for example. In this embodiment, the set of vias are connected to at least one metallization layer 419, which is formed in an additional frontside ILD layer 431. Specifically, via 419-1 connects the at least one metallization layer 419 and the source/drain contact 451-1, and via 419-2 connects the at least one metallization layer 419 to a first contact layer 414, a second contact layer 416, and a portion of a third contact layer 424. The at least one metallization layer 419 is connected to frontside BEOL interconnects 455, and a carrier wafer 457 is bonded to the frontside BEOL interconnects 155. The frontside BEOL interconnects 455 can include various BEOL interconnect structures which may electrically connect to the at least one metallization layer 419.

The semiconductor structure 400 also includes backside interconnects 470, which are formed on a bottom surface of the ILD layer 409. The backside interconnects 470 can include various backside power delivery network (BSPDN) structures such as, but not necessarily limited to, interconnects in a power supply path from voltage regulator modules (VRMs) to circuits. The interconnects can comprise, for example, power and ground planes in circuit boards, cables, connectors, and capacitors associated with a power supply. Backside power delivery prevents BEOL routing congestion, resulting in power performance benefits.

Notably, the bottom FET structure is connected to one or more frontside signal lines (e.g., corresponding to the frontside BEOL interconnects 455) using the via 418-2 and respective portions of the first contact layer 414, the second contact layer 416, and the third contact layer 424, which are separated from portions of the first contact layer 414-2, the second contact layer 416-2, and the portion of the third contact layer 424 of the adjacent FET structures.

In an illustrative embodiment, a semiconductor structure includes a first set of one or more vertically stacked contacts, a second set of one or more vertically stacked contacts, a first set of stacked transistor devices associated with the first set of vertically stacked contacts, and a second set of stacked transistor devices associated with the second set of vertically stacked contacts. The second set of stacked transistor devices is adjacent to the first set of stacked transistor devices, and a dielectric isolation pillar is disposed between the first set of vertically stacked contacts and the second set of vertically stacked contacts.

In embodiments, the first set of one or more vertically stacked contacts may include a single contact.

In embodiments, the semiconductor structure may further include a shallow trench isolation region disposed below respective bottommost contacts of the first set of one or more vertically stacked contacts and the second set of one or more vertically stacked contacts.

In embodiments, the dielectric isolation pillar may extend at least partially into the shallow trench isolation region.

In embodiments, the dielectric isolation pillar may extend down from top surfaces of respective uppermost contacts of the first set of one or more vertically stacked contacts and the second set of one or more vertically stacked contacts to at least bottom surfaces of the respective bottommost contacts of the first set of one or more vertically stacked contacts and the second set of one or more vertically stacked contacts.

In embodiments, the semiconductor structure may include at least one via structure disposed on the top surface of at least one of the respective uppermost top contacts, wherein the dielectric isolation pillar extends down from the at least one via structure.

In embodiments, the first set of stacked transistor devices may include a top transistor device comprising one or more top channel layers, and a bottom transistor device comprising one or more bottom channel layers.

In embodiments, the semiconductor structure may include at least one gate structure associated with the first set of stacked transistor devices, where the at least one gate structure comprises at least one metal gate and one or more gate spacers.

In embodiments, the dielectric isolation pillar may extend to below a level corresponding to a bottom surface of the bottom transistor device.

In embodiments, the top transistor device may include one of a p-type transistor device and an n-type transistor device, and the bottom transistor device may include the other one of the p-type transistor device and the n-type transistor device.

In embodiments, the semiconductor structure may include a backside power delivery network comprising a first metal level, a second metal level, and a third metal level.

In embodiments, the dielectric isolation pillar may extend down to at least one of the first metal level, the second metal level, and the third metal level of the backside power delivery network.

In embodiments, the dielectric isolation pillar may include a dielectric material comprising silicon and nitrogen.

In embodiments, the dielectric material may include one or more of carbon and oxygen.

In an illustrative embodiment, a semiconductor structure includes a first set of vertically stacked metal contacts including a first top metal contact, a first center metal contact, and a first bottom metal contact, a second set of vertically stacked metal contacts including a second top metal contact, a second center metal contact, and a second bottom metal contact, a first stacked nanosheet structure contacting the first set of vertically stacked metal contacts, and a second stacked nanosheet structure contacting the second set of vertically stacked metal contacts. The semiconductor structure also includes a dielectric isolation pillar disposed between the first set of vertically stacked metal contacts and the second set of vertically stacked metal contacts.

In embodiments, the semiconductor structure may include a shallow trench isolation region disposed below the first bottom metal contact and the second bottom metal contact, wherein the dielectric isolation pillar extends at least partially into the shallow trench isolation region.

In embodiments, the dielectric isolation pillar may extend down from at least a top of the first top metal contact and the second top metal contact to at least a bottom of the first bottom metal contact and the second bottom metal contact.

In embodiments, the semiconductor structure may include a backside power delivery network comprising a first metal level, a second metal level, and a third metal level, where the dielectric isolation pillar extends down to at least one of the first metal level, the second metal level, and the third metal level of the backside power delivery network.

In embodiments, the first stacked nanosheet structure may include a first set of channel layers corresponding to a first transistor device, and a second set of channel layers corresponding to a second transistor device, where the first transistor device is below the second transistor device.

In yet another illustrative embodiment, a method includes forming a first transistor structure, forming a second transistor structure, forming a first set of vertically stacked contacts including a first top contact, a first center contact, and a first bottom contact, the first set of vertically stacked contacts contacting the first transistor structure, forming a second set of vertically stacked contacts including a second top contact, a second center contact, and a second bottom contact, the second set of vertically stacked contacts contacting the second transistor structure, and forming a dielectric isolation pillar between the first set of vertically stacked contacts and the second set of vertically stacked contacts.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments described herein provide techniques and structures for forming a semiconductor device with a dielectric isolation structure. In some embodiments, the dielectric isolation structure is formed between metal contacts of adjacent FET structures. Such embodiments can advantageously prevent metal contacts (e.g., backside metal contacts) from shorting, thereby allowing further cell scaling, for example.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a first set of one or more vertically stacked contacts;
a second set of one or more vertically stacked contacts;
a first set of stacked transistor devices associated with the first set of one or more vertically stacked contacts;
a second set of stacked transistor devices associated with the second set of one or more vertically stacked contacts, wherein the second set of stacked transistor devices is adjacent to the first set of stacked transistor devices; and
a dielectric isolation pillar disposed between the first set of one or more vertically stacked contacts and the second set of one or more vertically stacked contacts.

2. The semiconductor structure of claim 1, wherein the first set of one or more vertically stacked contacts comprises a single contact.

3. The semiconductor structure of claim 1, further comprising:
a shallow trench isolation region disposed below respective bottommost contacts of the first set of one or more vertically stacked contacts and the second set of one or more vertically stacked contacts.

4. The semiconductor structure of claim 3, wherein the dielectric isolation pillar extends at least partially into the shallow trench isolation region.

5. The semiconductor structure of claim 1, wherein the dielectric isolation pillar extends down from top surfaces of respective uppermost contacts of the first set of one or more vertically stacked contacts and the second set of one or more vertically stacked contacts to at least bottom surfaces of respective bottommost contacts of the first set of one or more vertically stacked contacts and the second set of one or more vertically stacked contacts.

6. The semiconductor structure of claim 5, further comprising at least one via structure disposed on the top surface of at least one of the respective uppermost contacts, wherein the dielectric isolation pillar extends down from the at least one via structure.

7. The semiconductor structure of claim 1, wherein the first set of stacked transistor devices comprises:
a top transistor device comprising one or more top channel layers; and
a bottom transistor device comprising one or more bottom channel layers.

8. The semiconductor structure of claim 7, further comprising:
at least one gate structure associated with the first set of stacked transistor devices, wherein the at least one gate structure comprises at least one metal gate and one or more gate spacers.

9. The semiconductor structure of claim 8, wherein the dielectric isolation pillar extends to below a level corresponding to a bottom surface of the bottom transistor device.

10. The semiconductor structure of claim 8, wherein the top transistor device comprises one of a p-type transistor device and an n-type transistor device, and the bottom transistor device comprises the other one of the p-type transistor device and the n-type transistor device.

11. The semiconductor structure of claim 1, further comprising:
a backside power delivery network comprising a first metal level, a second metal level, and a third metal level.

12. The semiconductor structure of claim 11, wherein the dielectric isolation pillar extends down to at least one of the first metal level, the second metal level, and the third metal level of the backside power delivery network.

13. The semiconductor structure of claim 1, wherein the dielectric isolation pillar comprises a dielectric material comprising silicon and nitrogen.

14. The semiconductor structure of claim 13, wherein the dielectric material further comprises one or more of carbon and oxygen.

15. A semiconductor structure comprising:
a first set of vertically stacked metal contacts comprising a first top metal contact, a first center metal contact, and a first bottom metal contact;
a second set of vertically stacked metal contacts comprising a second top metal contact, a second center metal contact, and a second bottom metal contact;
a first stacked nanosheet structure contacting the first set of vertically stacked metal contacts;
a second stacked nanosheet structure contacting the second set of vertically stacked metal contacts; and
a dielectric isolation pillar disposed between the first set of vertically stacked metal contacts and the second set of vertically stacked metal contacts.

16. The semiconductor structure of claim 15, further comprising a shallow trench isolation region disposed below the first bottom metal contact and the second bottom metal contact, wherein the dielectric isolation pillar extends at least partially into the shallow trench isolation region.

17. The semiconductor structure of claim 15, wherein the dielectric isolation pillar extends down from at least a top of the first top metal contact and the second top metal contact to at least a bottom of the first bottom metal contact and the second bottom metal contact.

18. The semiconductor structure of claim 15, further comprising a backside power delivery network comprising a first metal level, a second metal level, and a third metal level, wherein the dielectric isolation pillar extends down to at least one of the first metal level, the second metal level, and the third metal level of the backside power delivery network.

19. The semiconductor structure of claim 15, wherein the first stacked nanosheet structure comprises:
a first set of channel layers corresponding to a first transistor device; and
a second set of channel layers corresponding to a second transistor device, wherein the first transistor device is below the second transistor device.

20. A method, comprising:
forming a first transistor structure;
forming a second transistor structure;
forming a first set of vertically stacked contacts comprising a first top contact, a first center contact, and a first bottom contact, the first set of vertically stacked contacts contacting the first transistor structure;
forming a second set of vertically stacked contacts comprising a second top contact, a second center contact, and a second bottom contact, the second set of vertically stacked contacts contacting the second transistor structure; and
forming a dielectric isolation pillar between the first set of vertically stacked contacts and the second set of vertically stacked contacts.
